(19) United States
(12) Patent Application Publication
(10) Pub. No.: US 2008/0032491 A1
(43) Pub. Date: Feb. 7, 2008

(54) Wafer backside particle removal for track tools

(75) Inventor: Harald Herchen, Los Altos, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: SOKUDO CO., LTD., Kyoto (JP)

(21) Appl. No.: 11/501,201

(22) Filed: Aug. 7, 2006

(51) Int. Cl. H01L 21/322

(52) U.S. Cl. 438/476

(57) ABSTRACT

An apparatus for removing one or more backside particles from a semiconductor substrate. The apparatus includes a substrate support member adapted to support the semiconductor substrate. The substrate has a substrate diameter, a substrate frontside, and a substrate backside. The apparatus also includes a curing ring having an annular shape and a curing ring support member adapted to position the curing ring at a predetermined distance from the backside of the semiconductor substrate, thereby defining a removal region. The apparatus further includes a phase change material dispense system adapted to provide a phase change material to the removal region and an ultraviolet source adapted to irradiate the phase change material.

### BACKGROUND OF THE INVENTION

The present invention relates generally to the field of substrate processing equipment. More particularly, the present invention relates to the removal of particles on the backside of a semiconductor substrate. Merely by way of example, the method and apparatus of the present invention are used to remove particles using a liquid polymer cured by exposure to ultraviolet radiation. The method and apparatus can be applied to other processes for semiconductor substrates, for example those used in the formation of integrated circuits.

Modern integrated circuits contain millions of individual elements that are formed by patterning the materials, such as silicon, metal and/or dielectric layers, which make up the integrated circuit, to sizes that are small fractions of a micrometer. The technique used throughout the industry for forming such patterns is photolithography. A typical photolithography process sequence generally includes depositing one or more uniform photoresist (resist) layers on the surface of a substrate, drying and curing the deposited layers, patterning the substrate by exposing the photoresist layer to electromagnetic radiation that is suitable for modifying the exposed layer, and then developing the patterned photoresist layer.

It is common in the semiconductor industry for many of the steps associated with the photolithography process to be performed in a multi-chamber processing system (e.g., a cluster tool) that has the capability to sequentially process semiconductor wafers in a controlled manner. One example of a cluster tool that is used to deposit (i.e., coat) and develop a photoresist material is commonly referred to as a track lithography tool.

Track lithography tools typically include a mainframe that houses multiple chambers (which are sometimes referred to herein as stations) dedicated to performing the various tasks associated with pre- and post-lithography processing. There are typically both wet and dry processing chambers within track lithography tools. Wet chambers include coat and/or develop bowls, while dry chambers include thermal control units that house bake and/or chill plates. Track lithography tools also frequently include one or more pod/cassette mounting devices, such as an industry standard FOUP (front opening unified pod), to receive substrates from and return substrates to the clean room, multiple substrate transfer robots to transfer substrates between the various chambers/stations of the track tool, and an interface that allows the tool to be operatively coupled to a lithography exposure tool in order to transfer substrates into the exposure tool and receive substrates from the exposure tool after the substrates are processed within the exposure tool.

Over the years there has been a strong push within the semiconductor industry to shrink the size of semiconductor devices. As device size has decreased, the importance of reducing the presence of contaminant particles has increased since such particles may lead to the formation of defects during the semiconductor fabrication process. In order to maintain high manufacturing yield and low costs, the detection and removal of contaminant particles is desirable. Particles present on the wafer bevel may be dislodged and adhere to the front side of the wafer, potentially damaging integrated circuits formed on the front side of the wafer. Moreover, if particles present on the wafer bevel are dislodged and adhere to the backside of the wafer, non-planarity during lithography may result in lithographic depth of focus errors.

Some particle removal systems utilize megasonic cleaning systems that subject the contents of a liquid bath to a beam of megasonic energy produced by a transducer. Particles are removed from a substrate suspended in the liquid bath. However, megasonic cleaning may damage structures formed on the substrate and may not remove small particles present in high-aspect ratio features. Another particle removal technique uses an aqueous foam produced by the simple mixing of non-soluble expansion gases, for example, air, to remove particles. Both megasonic and foam cleaning techniques are wet processes and may require complicated processing apparatus. Therefore, there is a need in the art for improved methods and apparatus for removing particles on the backside of a semiconductor substrate in a track lithography tool.

### SUMMARY OF THE INVENTION

According to embodiments of the present invention, techniques related to the field of substrate processing equipment are provided. More particularly, the present invention relates to the removal of particles on the backside of a semiconductor substrate. Merely by way of example, the method and apparatus of the present invention are used to remove particles using a liquid polymer cured by exposure to ultraviolet radiation. The method and apparatus can be applied to other processes for semiconductor substrates, for example those used in the formation of integrated circuits.

According to an embodiment of the present invention, an apparatus for removing one or more backside particles from a semiconductor substrate is provided. The apparatus includes a substrate support member adapted to support the semiconductor substrate. The semiconductor substrate has a substrate diameter, a substrate frontside, and a substrate backside. The apparatus also includes a curing ring having an annular shape and a curing ring support member adapted to position the curing ring at a predetermined distance from the substrate backside, thereby defining a removal region. The apparatus also includes a phase change material dispense system adapted to provide a phase change material to the removal region and an ultraviolet source adapted to irradiate the phase change material.

According to another embodiment of the present invention, a method of removing one or more backside particles from a semiconductor substrate is provided. The method includes supporting the semiconductor substrate using a substrate support member. The semiconductor substrate has a substrate diameter, a substrate frontside, and a substrate backside. The method also includes defining a removal region by positioning a curing ring at a predetermined distance from the substrate backside and dispensing a phase change material into the removal region. The phase change material includes a liquid portion in contact with the one or more backside particles. The method further includes irradiating the phase change material with ultraviolet radiation and increasing a separation between the curing ring and the substrate backside to remove the one or more backside particles.

According to a specific embodiment of the present invention, a track lithography tool including a particle removal module is provided. The particle removal module includes a substrate support member adapted to support a semiconductor substrate and a curing ring having an annular shape. The particle removal module also includes a curing ring support member adapted to position the curing ring at a predetermined distance from a backside of the semiconductor substrate, thereby defining a removal region. The particle removal module further includes a phase change material dispense system adapted to provide a phase change material to the removal region and an ultraviolet source adapted to irradiate the phase change material.

Many benefits are achieved by way of the present invention over conventional techniques. For example, an embodiment provides a method of removing backside wafer particles that reduces cleaning residue and the thermal impact on the substrate undergoing the particle removal process. Additionally, embodiments of the present invention provide particle removal techniques and systems that are performed rapidly, thereby increasing wafer throughput. Depending upon the embodiment, one or more of these benefits, as well as other benefits, may be achieved. These and other benefits will be described in more detail throughout the present specification and more particularly below in conjunction with the following drawings.

### BRIEF DESCRIPTION OF THE DRAWINGS

FIG. 1 is a simplified plan view of an embodiment of a track lithography tool according to an embodiment of the present invention;

FIG. 2 is a simplified schematic diagram illustrating a cross-sectional view of a wafer backside particle removal apparatus according to an embodiment of the present invention;

FIG. 3 is a simplified schematic diagram illustrating a cross-sectional view of a portion of a wafer backside particle removal apparatus at a first time according to an embodiment of the present invention;

FIG. 4 is a simplified schematic diagram illustrating a cross-sectional view of a portion of a wafer backside particle removal apparatus at a second time according to an embodiment of the present invention; and

FIG. 5 is a simplified flowchart illustrating a method of removing particles on a wafer backside according to an embodiment of the present invention.

### DETAILED DESCRIPTION OF SPECIFIC EMBODIMENTS

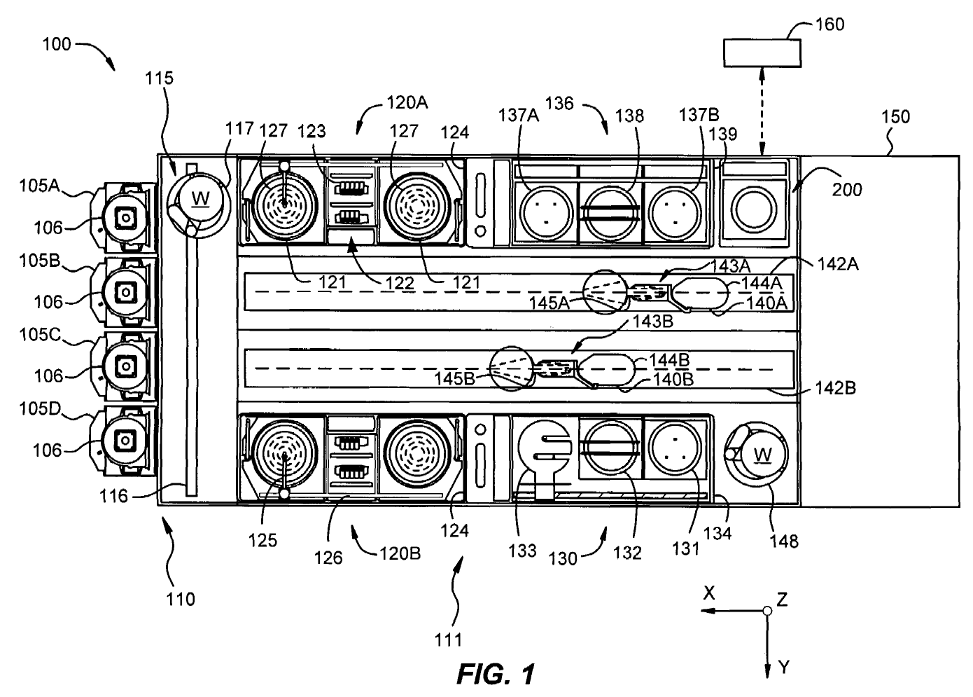

FIG. 1 is a plan view of an embodiment of a track lithography tool 100 in which the embodiments of the present invention may be used. As illustrated in FIG. 1, track lithography tool 100 contains a front end module 110 (sometimes referred to as a factory interface or FI) and a process module 111. In other embodiments, the track lithography tool 100 includes a rear module (not shown), which is sometimes referred to as a scanner interface. Front end module 110 generally contains one or more pod assemblies or FOUPS (e.g., items 105A-D) and a front end robot assembly 115 including a horizontal motion assembly 116 and a front end robot 117. The front end module 110 may also include front end processing racks (not shown). The one or more pod assemblies 105A-D are generally adapted to accept one or more cassettes 106 that may contain one or more substrates or wafers, “W,” that are to be processed in track lithography tool 100. The front end module 110 may also contain one or more pass-through positions (not shown) to link the front end module 110 and the process module 111.

Process module 111 generally contains a number of processing racks 120A, 120B, 130, and 136. As illustrated in FIG. 1, processing racks 120A and 120B each include a coater/developer module with shared dispense 124. A coater/developer module with shared dispense 124 includes two coat bowls 121 positioned on opposing sides of a shared dispense bank 122, which contains a number of nozzles 123 providing processing fluids (e.g., bottom anti-reflection coating (BARC) liquid, resist, developer, and the like) to a wafer mounted on a substrate support 127 located in the coat bowl 121. In the embodiment illustrated in FIG. 1, a dispense arm 125 sliding along a track 126 is able to pick up a nozzle 123 from the shared dispense bank 122 and position the selected nozzle over the wafer for dispense operations. Of course, coat bowls with dedicated dispense banks are provided in alternative embodiments.

Processing rack 130 includes an integrated thermal unit 134 including a bake plate 131, a chill plate 132, and a shuttle 133. The bake plate 131 and the chill plate 132 are utilized in heat treatment operations including post exposure bake (PEB), post-resist bake, and the like. In some embodiments, the shuttle 133, which moves wafers in the x-direction between the bake plate 131 and the chill plate 132, is chilled to provide for initial cooling of a wafer after removal from the bake plate 131 and prior to placement on the chill plate 132. Moreover, in other embodiments, the shuttle 133 is adapted to move in the z-direction, enabling the use of bake and chill plates at different z-heights. Processing rack 136 includes an integrated bake and chill unit 139, with two bake plates 137A and 137B served by a single chill plate 138.

One or more robot assemblies (robots) 140 are adapted to access the front-end module 110, the various processing modules or chambers retained in the processing racks 120A, 120B, 130, and 136, and the scanner 150. By transferring substrates between these various components, a desired processing sequence can be performed on the substrates. The two robots 140 illustrated in FIG. 1 are configured in a parallel processing configuration and travel in the x-direction along horizontal motion assembly 142. Utilizing a mast structure (not shown), the robots 140 are also adapted to move in a vertical (z-direction) and horizontal directions, i.e., transfer direction (x-direction) and a direction orthogonal to the transfer direction (y-direction). Utilizing one or more of these three directional motion capabilities, robots 140 are able to place wafers in and transfer wafers between the various processing chambers retained in the processing racks that are aligned along the transfer direction.

Referring to FIG. 1, the first robot assembly 140A and the second robot assembly 140B are adapted to transfer substrates to the various processing chambers contained in the processing racks 120A, 120B, 130, and 136. In one embodiment, to perform the process of transferring substrates in the track lithography tool 100, robot assembly 140A and robot assembly 140B are similarly configured and include at least one horizontal motion assembly 142, a vertical motion assembly 144, and a robot hardware assembly 143 supporting a robot blade 145 robot assemblies 140 are in communication with a system controller 160. In the embodiment illustrated in FIG. 1, a rear robot assembly 148 is also provided.

The scanner 150, which may be purchased from Canon USA, Inc. of San Jose, Calif., Nikon Precision Inc. of Belmont, Calif., or ASML US, Inc. of Tempe Ariz., is a lithographic projection apparatus used, for example, in the manufacture of integrated circuits (ICs). The scanner 150 exposes a photosensitive material (resist), deposited on the substrate in the cluster tool, to some form of electromagnetic radiation to generate a circuit pattern corresponding to an individual layer of the integrated circuit (IC) device to be formed on the substrate surface.

Each of the processing racks 120A, 120B, 130, and 136 contain multiple processing modules in a vertically stacked arrangement. That is, each of the processing racks may contain multiple stacked coater/developer modules with shared dispense 124, multiple stacked integrated thermal units 134, multiple stacked integrated bake and chill units 139, or other modules that are adapted to perform the various processing steps required of a track photolithography tool. As examples, coater/developer modules with shared dispense 124 may be used to deposit a bottom antireflective coating (BARC) and/or deposit and/or develop photoresist layers. Integrated thermal units 134 and integrated bake and chill units 139 may perform bake and chill operations associated with hardening BARC and/or photoresist layers after application or exposure.

In one embodiment, a system controller 160 is used to control all of the components and processes performed in the cluster tool 100. The controller 160 is generally adapted to communicate with the scanner 150, monitor and control aspects of the processes performed in the cluster tool 100, and is adapted to control all aspects of the complete substrate processing sequence. The controller 160, which is typically a microprocessor-based controller, is configured to receive inputs from a user and/or various sensors in one of the processing chambers and appropriately control the processing chamber components in accordance with the various inputs and software instructions retained in the controller's memory. The controller 160 generally contains memory and a CPU (not shown) which are utilized by the controller to retain various programs, process the programs, and execute the programs when necessary. The memory (not shown) is connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU. The support circuits (not shown) are also connected to the CPU for supporting the processor in a conventional manner. The support circuits may include cache, power supplies, clock circuits, input/output circuitry, subsystems, and the like all well known in the art. A program (or computer instructions) readable by the controller 160 determines which tasks are performable in the processing chamber(s). Preferably, the program is software readable by the controller 160 and includes instructions to monitor and control the process based on defined rules and input data.

It is to be understood that embodiments of the invention are not limited to use with a track lithography tool such as that depicted in FIG. 1. Instead, embodiments of the invention may be used in any track lithography tool including the many different tool configurations described in U.S. patent application Ser. No. 11/315,984, entitled “Cartesian Robot Cluster Tool Architecture” filed on Dec. 22, 2005, which is hereby incorporated by reference for all purposes and including configurations not described in the above referenced application.

Referring to FIG. 1, a wafer backside particle removal apparatus 200 is provided as a module in the track lithography tool 100. The wafer backside particle removal apparatus 200 is serviced by one or both of the robot assemblies 140 and is utilized, as described more fully throughout the present specification, to remove particles present on the backside of a wafer or substrate. The use of the wafer backside particle removal apparatus 200 may occur before or after several of the wafer processes performed within the track lithography tool 100. These wafer processes include coat, develop, bake, chill, exposure, and the like. In a particular embodiment, the substrate is examined for particles prior to processing by the scanner and detected particles are removed.

Merely by way of example, particles on the backside of a substrate are detected using a wafer backside particle detection apparatus as described in co-pending and commonly assigned U.S. patent application Ser. No. 11/411,422, filed on Apr. 25, 2006, and incorporated by reference herein in its entirety. Additionally, particles on the bevel of a wafer are detected using a wafer bevel particle detection apparatus as described in co-pending and commonly assigned U.S. patent application Ser. No. 11/412,058, filed on Apr. 25, 2006, and incorporated by reference herein in its entirety. In alternative embodiments, the wafer backside particle removal apparatus 200 is located external to the track lithography tool 100 in a separate stand-alone process module. One of ordinary skill in the art would recognize many variations, modifications, and alternatives.

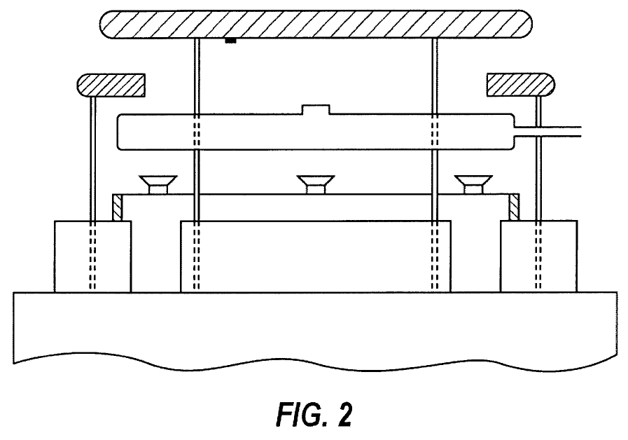

FIG. 2 is a simplified schematic diagram illustrating a cross-sectional view of a wafer backside particle removal apparatus according to an embodiment of the present invention. Wafer backside particle removal apparatus 200 includes a substrate support member 210 adapted to support a substrate 205 during particle removal operations. As will be evident to one of skill in the art, the backside 207 of the substrate 205 is generally free from active devices. In the embodiment of the present invention illustrated in FIG. 2, the substrate 205 is supported on lift pins 212, which may be actuated to move the substrate in the z-direction during wafer loading and unloading operations. Additionally, lift pins 212 are utilized in some embodiments to move the substrate in the z-direction prior to, during, or after particle removal processes.

In the embodiment illustrated in FIG. 2, the substrate is supported in a substantially horizontal position, although this is not required the present invention. Other wafer orientations, including tilted, and vertical are included within the scope of the present invention. Tilting of the substrate may be performed using lift pins 212 or by robotic mechanisms (not shown). One of ordinary skill in the art would recognize many variations, modifications, and alternatives.

Wafer backside particle removal apparatus 200 also includes a curing ring support member 220 and a curing ring 222. Substrate 205 has a substrate diameter D and a frontside 206 and a backside 207. The curing ring support member 220 is used to position the curing ring 222 at a predetermined distance from the backside 207 of the semiconductor substrate 205. The curing ring 222 has an annular shape and the diameter of the inner portion of the annulus is approximately equal to the substrate diameter D. As shown in FIG. 2, some embodiments of the present invention utilize an curing ring with an inner annulus diameter less than the substrate diameter and an outer annulus diameter greater than the substrate diameter. As described more fully throughout the present specification, the dimensions of the curing ring are selected to provide for desired cleaning of the substrate backside. Accordingly, the particular dimensions are selected based on the particular applications and the materials used during the particle removal process.

Wafer backside particle removal apparatus 200 also includes a phase change material dispense system 230 that is provided at a position below the curing ring 222. The phase change material dispense system 230 includes an inlet 231 and an orifice 232 from which a phase change material is dispensed into a removal region below the substrate 205. The removal region is discussed more fully throughout the specification and more particularly below. Other components of the phase change material dispense system 230, such as a phase change material reservoir (not shown), pumps (not shown), and control circuitry (not shown) are omitted in FIG. 2 for purpose of clarity. One of ordinary skill in the art would recognize many variations, modifications, and alternatives.

An ultraviolet (UV) source 240 is provided as part of the wafer backside particle removal apparatus 200. Suitable sources that provide UV radiation, including lamps, light emitting diodes (LEDs), lasers, and the like are included within the scope of the present invention. The spectral distribution of the UV source is selected in some embodiments to match the UV absorption properties of the phase change material, however this is not required by the present invention, as the spectral distribution of the UV source may be greater than one or more absorption bands of the phase change material. As illustrated in FIG. 2, the UV source 240 includes a series of emitters 242 although this is not required by the present invention. In other embodiments, an extended source having an aperture of substantially the same diameter as the substrate is utilized. In still other embodiments one or more UV sources with smaller apertures are scanned across the backside of the substrate, utilizing either mechanical scanning of the one or more UV sources or optical scanning of the radiation provided by the one or more UV sources. One of ordinary skill in the art would recognize many variations, modifications, and alternatives.

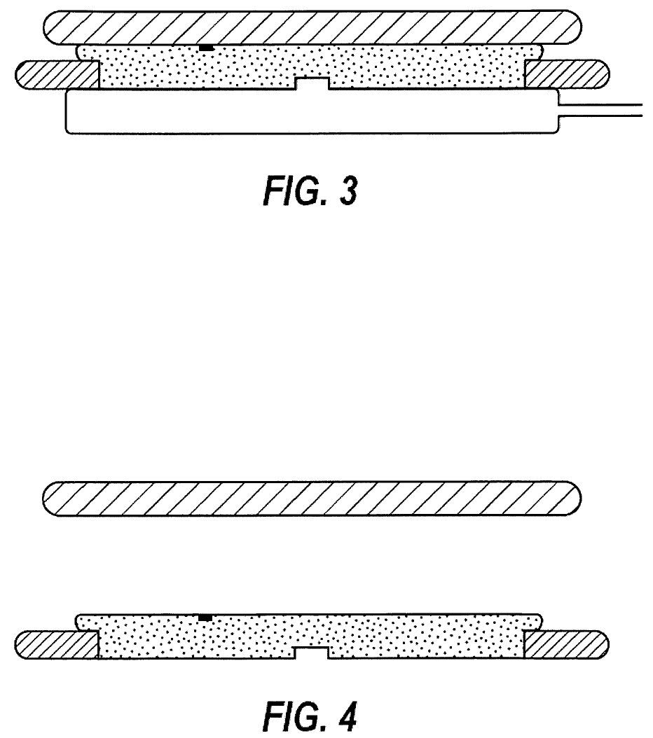

FIG. 3 is a simplified schematic diagram illustrating a cross-sectional view of a portions of a wafer backside particle removal apparatus at a first time according to an embodiment of the present invention. Referring to FIG. 3, the positioning of the curing ring 222 at a predetermined distance from the substrate backside 207 defines a removal region 224 between the curing ring 222, the substrate backside 207, and the phase change material dispense system. As illustrated in FIG. 3, the removal region 224 includes the space 310 between the annulus of the curing ring and the peripheral portions of the substrate. As discussed more fully below, phase change material in a liquid form is injected into the removal region, filling a portion of the space 310 between the annulus of the curing ring and the peripheral portions of the substrate.

The removal region 224 also includes the portion of the backside of the substrate adjacent the inner portions of the curing ring, illustrated by reference number 320. The removal region extends in the z-direction from the substrate backside 207 to the upper face of the phase change material dispense system 230. Thus, substantially the entire backside of the substrate is adjacent the removal region. According to some embodiments of the present invention, the removal region 224 does not extend in the z-direction above a plane parallel to the substrate backside 207. Thus, the wafer bevel is not included in the removal region according to some embodiments of the present invention.

In some embodiments, the phase change material is a polymer that undergoes a phase change from a liquid state to a solid state upon the application of UV radiation. Additional description of polymers utilized in some embodiments is provided below. References to polymers or polymer materials throughout the present specification is not intended to limit the scope of the present invention, but to represent an exemplary phase change material.

Embodiments of the present invention utilize a control system (not shown) to control the motion of the substrate support member 210, lift pins 212, the curing ring support member 220, the phase change dispense system 230, the UV source 240 and other system components. The control system, which is typically a microprocessor-based controller, is configured to receive inputs from a user and/or various sensors coupled to the system components and appropriately control the system components in accordance with the various inputs and software instructions retained in the controller's memory. Merely by way of example, the control system may be used in positioning of the substrate with respect to the curing ring, operation of the dispense system, and activation of the UV source during curing operations.

The controller generally contains memory and a CPU (not shown) which are utilized by the controller to retain various programs, process the programs, and execute the programs when necessary. The memory (not shown) is connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU. The support circuits (not shown) are also connected to the CPU for supporting the processor in a conventional manner. The support circuits may include cache, power supplies, clock circuits, input/output circuitry, subsystems, and the like all well known in the art. A program (or computer instructions) readable by the controller determines which tasks are performable using the various system components. Preferably, the program is software readable by the controller and includes instructions to monitor and control the process based on defined rules and input data.

Referring to FIG. 3, phase change material 330 has been dispensed in a liquid state from the phase change dispense system 230. The phase change material in the liquid state substantially fills the removal region 224, providing a uniform coating on the backside of the substrate. Thus, in FIG. 3, the removal region 224, including the space 310 between the annulus of the curing ring and the peripheral portions of the substrate and the portion 320 of the backside of the substrate adjacent the inner portions of the curing ring and the phase change material 330 are defined by the same physical space.

As shown in FIG. 3, the phase change material flows laterally over the upper surface of the curing ring. The actual amount of lateral flow will be a function of the predetermined distance between the substrate backside 207 and the curing ring 222, the viscosity of the phase change material and the pressure with which the liquid is injected into the removal region. One of ordinary skill in the art would recognize many variations, modifications, and alternatives.

According to an embodiment of the present invention, the phase change material is a polyimide material derived from a liquid polyimide precursor that is applied directly to the substrate backside 207 to form a precursor film, substantially without an intervening adhesion layer. In a particular embodiment, the phase change material is Experimental UV-Curable Clear Coating with the product designation 34-134, available from FSP Research, Inc. of Milford, Conn. The Experimental UV-Curable Clear Coating includes urethane acrylate oligomer (20-25% by weight), tripropyleneglycol diacrylate (25-30% by weight), tetrahydrofurfuryl acrylate (20-25% by weight), ethoxylated triacrylate (5-15% by weight), and a photoinitiator (3-6% by weight). The liquid is clear and lightly viscous and hardens in response to irradiation with a UV source. The fluences and spectral content of the UV source are generally selected to provide curing or hardening in a time period less than several seconds. Other suitable phase change materials may be utilized, including polyurethane and other UV curable polymers.

In an embodiment, the directly applied liquid polyimide precursor is dispensed in liquid form and is solidified using a UV curing process. After the UV curing process, the polyimide precursor hardens on the backside of the substrate to provide a solid material encapsulating particles present on the backside of the substrate. Referring to FIGS. 2 and 3, particle 250 is encapsulated in the cured phase change material. Encapsulation of the particle in the cured phase change material is not complete in some embodiments, as portions of the particle in contact with substrate backside are not in contact with the phase change material. As described more fully below and as illustrated in FIG. 3, encapsulation of the particle 250 in some embodiments entails a surface area of the particle in contact with the phase change material being greater than a surface area of the particle in contact with the substrate.

Although a single layer of the polymer is illustrated in FIG. 3, this is not required by embodiments of the present invention. In alternative embodiments, the UV curable material may be formed by applying a liquid precursor in layers comprising one or multiple types of polyimide precursors, and can also include other polymer precursors added to enhance the properties of the polyimide layer formed after the curing process.

During the UV curing process provided by a particular embodiment of the present invention, the liquid polyimide precursor film is cured to cross-link the polyimide precursor and form a hardened polyimide layer. According to embodiments of the present invention, UV curing provides a process that is rapid, for example, taking less than 1 minute. In a particular embodiment, the UV curing process is performed in less than several seconds or less than one second. Moreover, UV curing reduces the thermal impact of the hardening process, which is desirable since increases or decreases is substrate temperature may adversely impact track photolithography processes. Embodiments of the present invention differ from some conventional techniques in the amount of thermal impact produced during the particle removal process. In comparison with other particle removal techniques, hardening of the phase change material using a baking process may increase the substrate temperature, while some drying processes relying on evaporation may decrease the substrate temperature. Experiments performed by the inventor have demonstrated that temporal and spatial variations in substrate temperature, including variations across a substrate, impact the critical dimension (CD) control during a number of photolithography processes. Thus, the reduction of thermal impact as a result of the utilization of UV curing provides benefits not available from some other particle removal techniques.

The curing ring 222 is fabricated from a material that is substantially transparent to UV radiation, enabling the curing of phase change material 330 located in the space 310 between the annular portion of the curing ring and the peripheral portions of the substrate. Accordingly, the material spreading out laterally between the top surface of the curing ring and the backside of the substrate is cured and hardened. As illustrated in FIG. 4, this material provides a mechanical lip 410 that resists separation of the hardened phase change material from the curing ring after the completion of the curing process.

The thickness (measured in the z-direction) of the phase change material is a function of the dimensions of the removal region including the spacing between the curing ring and the backside of the substrate. In embodiments of the present invention, the thickness of the phase change material in the z-direction is a predetermined thickness. For example, the thickness is selected to provide for mechanical rigidity and to provide a uniform coating on the backside of the substrate. Merely by way of example, in an embodiment, the phase change material is a polymer and the thickness is about 0.3 mm thick. In another embodiment, the thickness is less than or equal to about 1.0 mm. Of course, the particular thickness will depend on the particular applications. One of ordinary skill in the art would recognize many variations, modifications, and alternatives.

As described more fully throughout the present specification, embodiments of the present invention limit the amount of phase change material in contact with the wafer bevel. Thus, in the embodiment illustrated in FIG. 3, none of the polymer is in contact with the wafer bevel. As described more fully in reference to FIG. 4 below, minimizing the physical contact between the hardened polymer and the wafer bevel facilitates the removal of the hardened polymer from the backside of the substrate, as no mechanical lips are provided surrounding the wafer bevel.

FIG. 4 is a simplified schematic diagram illustrating a cross-sectional view of a portion of a wafer backside particle removal apparatus at a second time according to an embodiment of the present invention. As illustrated in FIG. 4, the second time is at a time later than the first time. The phase change material has undergone the phase change from liquid to solid as a result of the UV curing process. As the curing ring 222 is moved in the z-direction away from the substrate 205, the hardened polymer 420 detaches from the substrate backside 207 and particle 250 encapsulated in the hardened polymer is thus removed from the backside of the substrate. It will be appreciated that methods and systems provided by embodiments of the present invention will remove a number of particles present on the backside of the substrate.

The adhesive properties of the phase change material are such that after the hardening or curing process, the hardened material experiences a low adhesion to the backside of the substrate. Typically, substrates including silicon, silicon oxide, silicon nitride, and the like are utilized in embodiments of the present invention. Thus, the phase change material, for example, a polymer, is applied in a liquid state, cured, and then removed as a solid piece of material, with little to no residual polymer material remaining on the backside of the substrate. Embodiments of the present invention reduce or eliminate post-particle removal chemical cleaning processes since any residual polymer material is minimized. Accordingly the number of cleaning steps are reduced through the use of embodiments of the present invention, resulting in a decrease in the total number of processing steps and an increase in system throughput.

Referring to FIG. 4, a lip 410 of hardened phase change material is cured as a result of UV radiation passing through the curing ring 222. During the separation of the hardened material and the backside of the substrate as illustrated in FIG. 4, mechanical force exerted on the curing ring will tend to remove all of the phase change material from contact with the substrate since the interlocking lip formed by the phase change material surrounds the inner diameter of the annular curing ring. Additionally, the transparency of the curing ring to UV radiation enables the liquid material at lip 410 to solidify, preventing the phase change material from remaining in a liquid state and in contact with the backside of the substrate when the curing ring is moved away from the substrate as shown in FIG. 4.

Embodiments of the present invention provide benefits not generally available using conventional particle removal techniques, including fluid rinses and/or air flows. For example, contaminants present in fluids may deposit on or precipitate out to form additional particles on the backside of the substrate. The solidification and subsequent removal of the polymer provided by some embodiments prevents these fluid contamination problems. Moreover, air flows typically provide limited ability to remove particles below a certain size or characterized by a certain adhesive strength. Embodiments of the present invention encapsulate particles in a manner that is substantially independent of particle size and remove particles for which the adhesive bond to the encapsulating polymer is greater than the bond to the substrate. In particular, for most particles, the surface area between the encapsulating polymer and the particle is significantly greater than the surface area between the particle and the substrate, increasing the likelihood that particles will be removed using the various embodiments described herein.

As will be evident to one of skill in the art, some embodiments provide for motion of the curing ring with respect to the substrate, whereas other embodiments of the present invention provide for motion of the substrate with respect to the curing ring. In yet other alternative embodiments, both the substrate support member and the curing ring support member are actuated to move the substrate and the curing with respect to each other. One of ordinary skill in the art would recognize many variations, modifications, and alternatives.

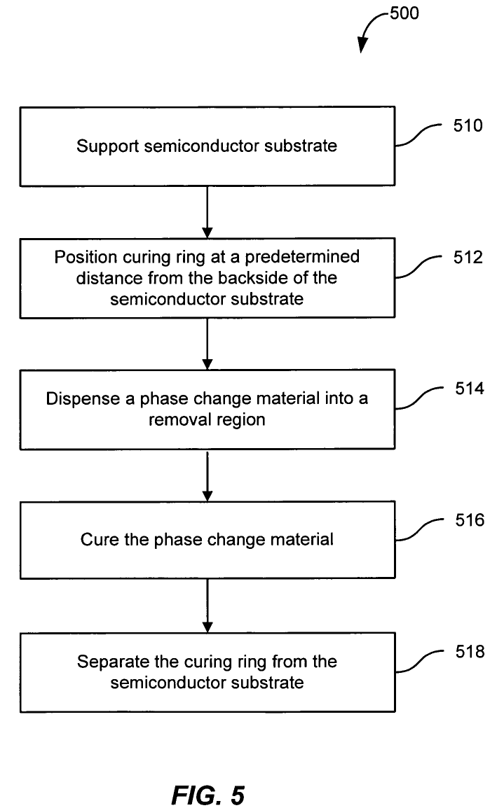

FIG. 5 is a simplified flowchart illustrating a method of removing particles on a wafer backside according to an embodiment of the present invention. The method 500 includes supporting the semiconductor substrate using a substrate support member (process 510). In some embodiments, the substrate is supported using lift pins operable to move the substrate up and down in the z-direction as illustrated in FIG. 1. A controller is utilized to actuate the lift pins as well as other system components.

The substrate is characterized by a substrate diameter, a substrate frontside, and a substrate backside. Integrated circuits and devices are fabricated on the frontside of the substrate using a variety of processes including photolithography processes performed using the track lithography tool illustrated in FIG. 1. During exposure in the scanner, backside particles that result in substrate tilt may adversely impact the focus and other optical properties of the exposure process. Accordingly, embodiments of the present invention remove backside particles prior to or after exposure steps. A curing ring is positioned at a predetermined distance from the backside of the semiconductor substrate (process 512). As described above, the curing ring is an annular ring fabricated from materials that are substantially transparent to UV radiation. These materials include sapphire, aluminum oxynitride, quartz, and the like. In an embodiment, the annular curing ring has an inner-diameter less than the diameter of the substrate and an outer-diameter greater than the substrate diameter.

A phase change material is dispensed into a removal region defined by the spacing between the backside of the semiconductor substrate, the curing ring, and the phase change material dispense system (process 514). In an embodiment, the phase change material dispense system includes a dispense housing with a planar surface opposing the backside of the semiconductor substrate. The phase change material, for example, a polymer, is initially in a liquid state during the dispense operation. After dispense, the phase change dispense system is removed, leaving a viscous liquid in contact with the backside of the substrate, at least portions of the top surface of the curing ring, and inner portions of the annulus. The phase change material is in contact with the one or more backside particles and encapsulates portions of the particles not in physical contact with the substrate. Thus, the particles are partially embedded in the phase change material as illustrated in FIG. 3.

The phase change material is cured (process 516) by irradiating the phase change material with ultraviolet radiation. Suitable sources, including lamps, LEDs, lasers, and the like are utilized to irradiate the phase change material. During the irradiation of the phase change material, the material undergoes a phase change from a liquid state to a solid state. According to embodiments of the present invention, the phase change occurs in under a minute, for example several seconds or less. After curing of the phase change material, the curing ring is separated from the semiconductor substrate (process 518). In some embodiments, the curing ring, is moved down in the z-direction and a lip of the phase change material extending onto the top of the curing ring interlocks the solidified phase change material and the curing ring. Separation of the phase change material results in the removal of particles partially embedded in the phase change material from the backside of the substrate.

According to embodiments of the present invention, the material utilized as the phase change material is characterized by a low adhesion to the semiconductor substrate, enabling removal of the solidified phase change material with minimal to no polymer residue remaining on the substrate.

It should be appreciated that the specific steps illustrated in FIG. 5 provide a particular method of removing a particle on a wafer backside according to an embodiment of the present invention. Other sequence of steps may also be performed according to alternative embodiments. For example, alternative embodiments of the present invention may perform the steps outlined above in a different order. Moreover, the individual steps illustrated in FIG. 5 may include multiple sub-steps that may be performed in various sequences as appropriate to the individual step. Furthermore, additional steps may be added or removed depending on the particular applications. One of ordinary skill in the art would recognize many variations, modifications, and alternatives.

The examples and embodiments described herein are for illustrative purposes only. Various modifications or changes in light thereof will be suggested to persons skilled in the art and are to be included within the spirit and purview of this application and scope of the appended claims. It is not intended that the invention be limited, except as indicated by the appended claims.

What is claimed is:

1. An apparatus for removing one or more backside particles from a semiconductor substrate, the apparatus comprising:
a substrate support member adapted to support the semiconductor substrate having a substrate diameter, a substrate frontside, and a substrate backside;
a curing ring having an annular shape;
a curing ring support member adapted to position the curing ring at a predetermined distance from the substrate backside, thereby defining a removal region;
a phase change material dispense system adapted to provide a phase change material to the removal region; and
an ultraviolet source adapted to irradiate the phase change material.

2. The apparatus of claim 1 wherein the substrate support is adapted to support the semiconductor substrate in a substantially horizontal position.

3. The apparatus of claim 1 wherein an inner-ring diameter of the curing ring is approximately equal to the substrate diameter.

4. The apparatus of claim 1 wherein an inner-ring diameter of the curing ring is less than the substrate diameter.

5. The apparatus of claim 1 wherein the curing ring comprises a material that is substantially transparent to ultraviolet radiation.

6. The apparatus of claim 5 wherein the material comprises at least one of sapphire, aluminum oxynitride, or quartz.

7. The apparatus of claim 1 wherein the substrate support member and the curing ring support member comprise a single support member.

8. The apparatus of claim 1 wherein the predetermined distance is less than 5 mm.

9. The apparatus of claim 8 wherein the predetermined distance is less than 1 mm.

10. The apparatus of claim 1 wherein the removal region comprises a portion extending from a surface of the curing ring to the substrate backside.

11. The apparatus of claim 1 wherein the phase change material comprises a liquid polymer.

12. A method of removing one or more backside particles from a semiconductor substrate, the method comprising:
supporting the semiconductor substrate using a substrate support member, wherein the semiconductor substrate has a substrate diameter, a substrate frontside, and a substrate backside;
defining a removal region by positioning a curing ring at a predetermined distance from the substrate backside;
dispensing a phase change material into the removal region, wherein the phase change material comprises a liquid portion in contact with the one or more backside particles;
irradiating the phase change material with ultraviolet radiation; and
increasing a separation between the curing ring and the substrate backside to remove the one or more backside particles.

13. The method of claim 12 wherein supporting the semiconductor substrate comprises using lift pins coupled to the substrate support member.

14. The method of claim 12 wherein positioning a curing ring at a predetermined distance from the backside of the semiconductor substrate comprises moving the curing ring with respect to the semiconductor substrate.

15. The method of claim 12 wherein irradiating the phase change material with ultraviolet radiation induces a phase change in the phase change material from a liquid state to a solid state.

16. The method of claim 15 wherein the phase change material comprises a polymer.

17. The method of claim 12 wherein the liquid portion of the phase change material in contact with the one or more backside particles comprises the liquid portion partially encapsulating the one or more backside particles.

18. The method of claim 12 wherein increasing a separation between the curing ring and the substrate backside comprises moving the curing ring with respect to the semiconductor substrate.

19. The method of claim 12 wherein increasing a separation between the curing ring and the backside of the semiconductor substrate further comprises separating the phase change material from the semiconductor substrate.

20. A track lithography tool including a particle removal module, the particle removal module comprising:
a substrate support member adapted to support a semiconductor substrate;
a curing ring having an annular shape;
a curing ring support member adapted to position the curing ring at a predetermined distance from a backside of the semiconductor substrate, thereby defining a removal region;
a phase change material dispense system adapted to provide a phase change material to the removal region; and
an ultraviolet source adapted to irradiate the phase change material.

21. The apparatus of claim 1 wherein the ring diameter is less than the semiconductor substrate diameter.

22. The apparatus of claim 1 wherein the curing ring comprises a material that is substantially transparent to ultraviolet radiation.

23. The apparatus of claim 1 wherein the phase change material comprises a polymer.

24. The apparatus of claim 23 wherein the polymer undergoes a phase change from a liquid state to a solid state in response to radiation from the ultraviolet source.
